(19) United States
(12) Patent Application Publication
(10) Pub. No.: US 2023/0420703 A1
(43) Pub. Date: Dec. 28, 2023

(54) DEVICE AND METHOD FOR TRANSFERRING A CATALYST-COATED MEMBRANE OR A GAS DIFFUSION LAYER

(71) Applicant: OPTIMA life science GmbH, Schwäbisch Hall (DE)

(72) Inventors: Norbert Dylla, Vellberg (DE); Johannes Jansen, Michelfeld (DE); Rolf Grotehusmann, Mainhardt (DE); Jürgen Gronemann, Ilshofen (DE); Philipp Winterer, Rudersberg (DE); Karl-Heinz Halder, Rosengarten (DE)

(73) Assignee: OPTIMA life science GmbH, Schwäbisch Hall (DE)

(21) Appl. No.: 18/036,370

(22) PCT Filed: Oct. 8, 2021
(86) PCT No.: PCT/EP2021/077847

§ 371 Date: May 10, 2023

(30) Foreign Application Priority Data
Nov. 12, 2020 (DE) 10 2020 214 263.7

(51) Int. Cl. H01M 8/0297; H01M 8/1004; B32B 37/22; B32B 37/00; B65H 20/02; B65H 37/00

(52) U.S. Cl. CPC H01M 8/0297; H01M 8/1004; B32B 37/22; B32B 37/025; B65H 20/02; B65H 37/002; B32B 2457/10

(57) ABSTRACT

The invention relates to a device and to a method for transferring a functional layer, in particular a catalyst-coated membrane (2) and/or a gas diffusion layer for a membrane electrode assembly, onto a first material web, wherein: precuts (20) of a functional layer are transferred onto a moving counter surface with a first spacing (x1); the precuts (20) are supplied by means of a second material web (3) with a second spacing; the first spacing (x1) is greater than the second spacing (x2); the second material web (5), at least in a handover portion for carrying over a precut (20) moves synchronously with a conveying speed of the counter surface and is braked relative to the conveying speed to change the spacing; and the dispensing edge (6) in the first transport direction (1) relative to the second material web (5) is adjusted in order to create a braking and acceleration section for the precuts (20) moving discontinuously with the second material web (5).

### TECHNICAL FIELD AND PRIOR ART

The invention relates to an apparatus and a method for transferring a functional layer to a moving first material web, in particular for transferring a catalyst-coated membrane and/or a gas diffusion layer for a membrane electrode assembly.

Membrane electrode assemblies (MEA) for fuel cells comprising a catalyst-coated membrane (CCM) and two electrodes which are in the form of a cathode and an anode between which the membrane is arranged, are generally known. An MEA further comprises two gas diffusion layers (GDL) which are arranged at the sides, facing away from the membrane, of the electrodes. The GDL and the electrodes are in one configuration in the form of a common structure. A fuel cell can be constructed by means of a large number of membrane electrode assemblies which are arranged in a stack and the electrical powers of which are added together.

In the context of the application, a gas diffusion layer, a gas diffusion layer together with an electrode, a catalyst layer, a membrane, a catalyst-coated membrane, or a catalyst-coated membrane together with a polymer film are conjointly referred to as a functional layer.

DE 10 2015 010 440 A1 discloses a method for producing a membrane electrode assembly for a fuel cell, in which at least one frame material is provided as a continuous material web which is moved continuously in a transport direction and which thereby passes through a plurality of processing stations, wherein the membrane, the anode and the cathode are connected to the frame material in respective processing stations. The membrane is in this instance in one configuration provided as a blank. In other embodiments, the membrane is provided as a material web, wherein at the associated processing station a blank of the membrane is separated from the material web and connected to the frame material.

### Problem and Solution

An object of the invention is to provide an apparatus and a method for transferring a functional layer, in particular a membrane and/or a gas diffusion layer, to a moving material web for the production of membrane electrode assemblies which enable reliable handling of tension-sensitive materials, such as membranes or gas diffusion layers, and a precise transfer to the material web.

According to a first aspect, an apparatus for transferring a functional layer to a moving first material web, in particular for transferring a catalyst-coated membrane and/or a gas diffusion layer for a membrane electrode assembly of a fuel cell, is provided, which apparatus is configured to transfer blanks of the functional layer, in particular of the membrane and/or the gas diffusion layer, to a counter-face which is moved at a conveying speed with a first spacing, wherein the apparatus has a supply device for supplying the blanks on a second material web and a dispensing edge which extends transversely relative to the direction of the second material web and around which the second material web is guided in order to release the blanks while changing direction from a first transport direction to a second transport direction, wherein the blanks are arranged on the second material web with a second spacing, wherein the first spacing is greater than the second spacing, wherein the supply device is suitable for moving the second material web at least in a transfer section for transfer of a blank in a synchronous manner with respect to the conveying speed, and to brake the second material web at least in the transfer section for a change of spacing relative to the conveying speed, and wherein the dispensing edge is supported so as to be able to be adjusted in the first transport direction relative to the second material web and can be adjusted by means of an adjustment device in order to provide a braking and acceleration path for the blanks which are moved in a discontinuous manner with the second material web.

The terms “a”, “an”, etcetera, are used in connection with the application purely as indefinite articles and not as numerals. The terms “first”, “second”, etcetera, serve only to distinguish elements and do not indicate any hierarchy of the elements.

The counter-face may be the first material web or a surface of an intermediate device, for example, a roller.

The counter-face is moved at a conveying speed. In advantageous embodiments, a continuous movement of the counter-face is provided. The term “continuous movement” is used in the context of the application to refer to a movement in which a conveying speed during a transfer cycle, that is to say, from the beginning of the transfer of a blank to the beginning of the transfer of a subsequent blank, is constant or at least virtually constant. In this instance, in one embodiment, a gradual increase or decrease of the conveying speed over a transfer cycle is provided for.

The second material web is moved in a discontinuous manner relative to the conveying speed. The term “movement which is discontinuous relative to the conveying speed” is used to refer to a movement in which a transport speed of the material web is not continuously synchronous relative to the conveying speed. For a tension-free transfer of the blanks, the second material web is moved during the transfer at a first transport speed which is synchronous relative to the conveying speed of the counter-face, for example, the first material web. In order to increase the spacing, the second material web is kept stationary or is braked to a lower transport speed. In this case, a transfer is carried out in advantageous embodiments only when the blanks are moved synchronously with respect to the conveying speed.

In one embodiment, the first material web is a frame material web, as described in DE 10 2015 010 440 A1. In other embodiments, the material web is a carrier web which is used only to transport components of a membrane electrode assembly, but is separated therefrom prior to or with the completion of the membrane electrode assembly. On the first material web, in one embodiment, other components of the membrane electrode assembly are already provided, in particular in one embodiment anode or cathode blanks are already provided on the first material web, wherein the blanks of the functional layer, in particular of the membrane, can be precisely positioned thereon and can be connected thereto.

The blanks of the functional layer, in particular of the membrane and/or the gas diffusion layer, are produced in one embodiment by means of a kiss cut, wherein the functional layer, in particular the membrane and/or the gas diffusion layer, is provided as a laminate with the second material web and supplied to a cutting device. In this instance, in one embodiment residues of the functional layer remain on the second material web after the blanks have been released.

The term “transfer section” is used to refer to a section in which the blanks are transferred to the counter-face and/or are provided for a subsequent transfer.

For reliable release of the blanks from the second material web there is provided a dispensing edge which extends transversely relative to the direction of the second material web and around which the second material web is guided in order to release the blanks while changing direction from a first transport direction to a second transport direction. The term “dispensing edge” in the context of the application is used to refer to an edge which is used both to release and to transfer the blank to the counter-face. The dispensing edge can be configured in a suitable manner by the person skilled in the art according to the application, in particular also in order to separate remaining portions of the functional layer, in particular the membrane and/or the gas diffusion layer, which are intended to remain on the second material web from the blanks which are intended to be transferred. The dispensing edge is in one embodiment at least partially produced from a resilient material in order to compensate for occurrences of unevenness of the counter-face.

The dispensing edge is supported so as to be able to be adjusted in the first transport direction relative to the second material web and can be moved by means of an adjustment device in order to provide a braking and acceleration path for the blanks which are moved in a discontinuous manner with the second material web.

As a result of the adjustment movement, it is possible for the blanks to be moved by means of the second material web during the transfer exclusively in a synchronous manner with respect to the conveying speed of the counter-face. As a result of the movement of the dispensing edge relative to the second material web, a movement of the blanks over the dispensing edge and a resultant release of the blanks from the second material web during a braking and/or an acceleration, that is to say, as long as the second material web does not yet have or no longer has a transport speed required for the transfer, is prevented. It is thereby possible to prevent a front end of the blanks from being exposed, that is to say, being supported neither by the second material web nor by the counter-face. This is advantageous in particular for processing a catalyst-coated membrane for a membrane electrode assembly which generally has a low level of inherent rigidity.

The adjustment device is preferably further suitable for moving the dispensing edge relative to the first material web or an alternative counter-face in the direction toward or away from the counter-face in order to bring about a pressing force onto the blank during a transfer and in order to prevent a contact of the blanks or the second material web with the counter-face without transferring a blank. The term “movement of the dispensing edge in the first transport direction” in the context of the application is used to refer to a movement which at least has a significant component in the first transport direction. As a result of a movement of the dispensing edge relative to the counter-face, the first transport direction is not constant. During a transfer, the second material web is transported at an acute angle with respect to the counter-face or a tangent on the counter-face. During a stoppage, the first transport direction may extend substantially parallel with the transport direction of the counter-face or a tangent on the counter-face.

In one embodiment, a sensor device is provided in order to detect a position of a front end of a blank which is intended to be subsequently transferred and in order to control or regulate the adjustment device and/or a transport speed of the second material web accordingly. The sensor device comprises in one embodiment a sensor which is integrated in the dispensing edge or fitted on the dispensing edge.

The apparatus is suitable for moving the second material web for a transfer of a blank synchronously with respect to the conveying speed. The adjustment device for the dispensing edge is in one embodiment configured, when a blank is transferred, to adjust the dispensing edge relative to the second material web in the first transport direction backward and, when the second material web is braked and/or when the second material web is stationary, to adjust the dispensing edge relative to the second material web in the first transport direction forward. As a result of the adjustment movement of the dispensing edge in the first transport direction forward, a front end of a blank which is intended to be subsequently transferred onto the counter-face prior to an acceleration of the second material web to the transport speed of the counter-face is located upstream of the dispensing edge. When the second material web is accelerated, the dispensing edge in advantageous embodiments is kept stationary. The path between the front end of the blank and the dispensing edge acts as an acceleration path and is selected in such a manner that, when the desired transport speed is reached, the front end of the blank reaches a region adjacent to a front end of the dispensing edge so that by means of the dispensing edge when the transfer of the blank begins, a pressing force can be applied to the blank. In order to provide a corresponding acceleration path also for a subsequent blank, the dispensing edge is adjusted backward during the transfer of the blank. After completely transferring a blank, the second material web is braked, wherein the dispensing edge is adjusted forward in order to prevent a movement of the following blank over the dispensing edge during the braking of the material web. Whilst the second material web is stationary, there is in one embodiment no adjustment movement of the dispensing edge. In other embodiments, the dispensing edge whilst the second material web is stationary is adjusted further forward in order to provide a longer acceleration path.

In order to prevent, in the case of an offset of the dispensing edge, tensile stresses and/or bottlenecks as a result of shortenings or lengthenings of a movement path after the dispending edge, in one embodiment a discontinuously operable removal unit is provided. However, such a removal device demands a high level of control complexity. In advantageous embodiments, therefore, the second material web is guided downstream of the dispensing edge via a compensation device for a length compensation during a movement of the dispensing edge. In one embodiment, the compensation apparatus is forcibly controlled. A forcibly controlled compensation apparatus is particularly advantageous when acceleration and braking ramps of a movement profile of the dispensing edge are so powerful that a passively guided cylinder as a result of its inertia cannot follow sufficiently quickly and, without a forcible control, there is a risk of web tears or web tension losses occurring. The compensation device comprises in one embodiment a roller which is acted on pneumatically. A cost-effective compensation device is thereby provided.

The second material web is in one embodiment removed directly from a storage roll by means of a discontinuously operated roller and is after the transfer of the blanks wound up by means of a discontinuously operated roller. In other embodiments, the second material web is incorporated in a continuous process. For example, it is conceivable for a kiss cutting described above to be carried out in a continuous process. In order to achieve a discontinuous movement in the transfer section of the second material web, in one embodiment upstream and/or downstream of the transfer section, a dancer device is provided. In one embodiment, at least one of the dancer devices is forcibly guided. The forcible guiding or forced movement of the dancer device serves to prevent mass inertia effects and resilient action on the material web, which could lead to expansion variations. In an advantageous embodiment, for the discontinuous movement of the second material web in the transfer section the second material web is guided upstream and downstream of the transfer section via two forcibly guided dancer devices which are coupled to each other. The coupling uses in this instance the property that, for braking where applicable up to a stoppage and acceleration of the material web with the blank prior to the transfer location and the material web without a blank after the transfer location, length compensations which correspond in terms of value but which are directed in opposing directions are required. The coupling can be produced in this instance depending on the application mechanically or using control technology. The person skilled in the art can see that the configuration of the apparatus with two dancer devices which are coupled to each other is advantageous for a discontinuous movement of a material web along a transfer section not only in conjunction with a moving dispensing edge, but also in conjunction with alternative apparatuses for transferring a discontinuously transported material onto a continuously moved first material web.

In one embodiment, a transfer of the blanks is carried out from the second material web to a transfer device comprising a roller or a plurality of rollers. In other embodiments, the apparatus is configured to transfer the blanks directly from the second material web to the first material web. In other words, the first material web acts as a counter-face. In other words, an apparatus for transferring a functional layer, in particular a catalyst-coated membrane and/or a gas diffusion layer for a membrane electrode assembly, to a first material web which is moved at a conveying speed is provided, wherein the apparatus is configured to transfer blanks of the functional layer to the first material web with a first spacing.

According to a second aspect, a method for transferring a functional layer, in particular a catalyst-coated membrane and/or a gas diffusion layer for a membrane electrode assembly of a fuel cell, onto a first material web is provided, wherein blanks of the functional layer are transferred to a counter-face which is moved at a conveying speed with a first spacing, wherein the blanks are supplied by means of a second material web with a second spacing, wherein the first spacing is larger than the second spacing, wherein the second material web in order to release the blanks is guided around a dispensing edge which extends transversely relative to the direction of the second material web while changing direction from a first transport direction to a second transport direction, wherein the second material web at least in a transfer section for a transfer of a blank moves synchronously with respect to the conveying speed and to change spacing is braked relative to the conveying speed, and wherein the dispensing edge is adjusted in the first transport direction relative to the second material web in order to provide a braking and acceleration path for the blanks which are moved discontinuously with the second material web.

As a result of the discontinuous movement of the second material web relative to the conveying speed, a supply of the blanks by means of the second material web is possible without the blanks on the second material web having the same spacing as on the first material web. In this instance, in one embodiment, during a transfer of a blank at the conveying speed the dispensing edge is adjusted backward relative to the second material web in the first transport direction and, when the second material web is braked and/or when the second material web is stationary, the dispensing edge is adjusted forward relative to the second material web in the first transport direction.

In an advantageous embodiment, the second material web is guided downstream of the dispensing edge via a compensation device for a length compensation during a movement of the dispensing edge.

In one embodiment, there is further provision, for the discontinuous movement of the second material web in the transfer section, for the second material web to be guided upstream and downstream of the transfer section by means of two dancer devices which are coupled to each other.

In one embodiment, the blanks are transferred to the first material web indirectly by means of a transfer device which is provided between the first and second material web. In advantageous embodiments, the blanks are transferred directly from the second material web to the first material web, wherein the first material web acts as a counter-face. In other words, a method for transferring a functional layer, in particular a catalyst-coated membrane and/or a gas diffusion layer for a membrane electrode assembly, to a first material web which is moved at a conveying speed is provided, wherein blanks of the functional layer are transferred to the moved first material web with a first spacing.

### BRIEF DESCRIPTION OF THE DRAWINGS

Other advantages and aspects of the invention will be appreciated from the claims and from the description of embodiments of the invention which are explained below with reference to the Figures. In the drawings:

FIG. 1: shows a first embodiment of an apparatus for transferring a membrane to a continuously moved first material web at the beginning of a transfer of a blank from a second material web to the first material web,

FIG. 2: shows the apparatus according to FIG. 1 during the transfer of the blank and movement of a dispensing edge,

FIG. 3: shows the apparatus according to FIG. 1 after the transfer of the blank is complete,

FIG. 4: shows the apparatus according to FIG. 1 after the transfer of the blank is complete and when the second material web is braked,

FIG. 5: shows the apparatus according to FIG. 1 after the transfer of the blank is complete, with the second material web being stationary,

FIG. 6: shows the apparatus according to FIG. 1 prior to the transfer of the blank when the second material web is being accelerated,

FIG. 7: shows the apparatus according to FIGS. 1 to 6 with two dancer devices for a discontinuous movement of the second material web 5,

FIG. 8: shows a second embodiment of an apparatus for transferring a membrane to a continuously moved first material web, comprising a transfer device.

### DETAILED DESCRIPTION OF THE EMBODIMENTS

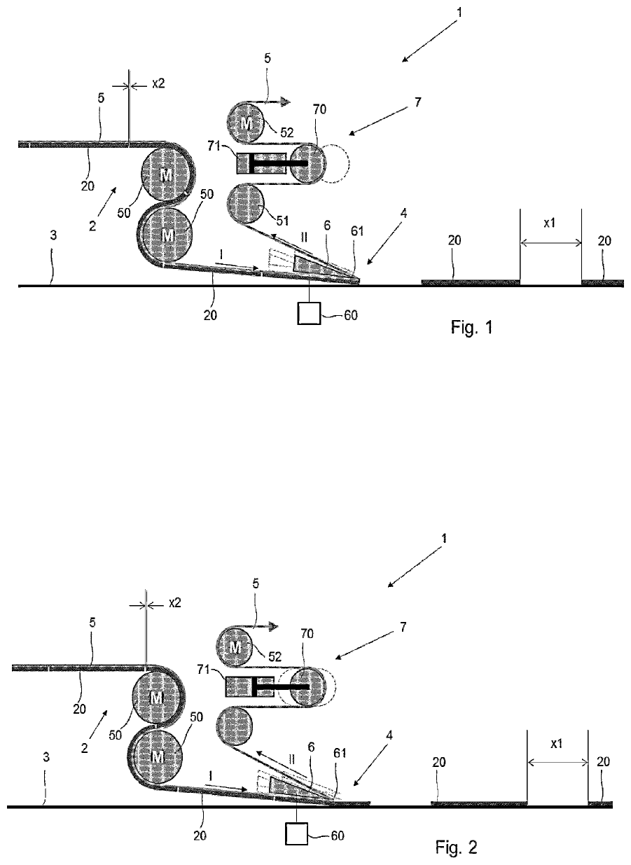

FIGS. 1 to 6 schematically show a first embodiment of an apparatus 1 for transferring a membrane 2 to a continuously moved first material web 3.

The membrane 2 is, for example, a catalyst-coated membrane for a membrane electrode assembly (not illustrated) of a fuel cell which is not illustrated. In place of a membrane 2, in an alternative embodiment a gas diffusion layer or another functional layer is transferred to the continuously moved first material web 3 by means of the apparatus 1.

The membrane 2 and/or an alternative functional layer is provided in the form of blanks 20 and transferred to the first material web 3 at a transfer location 4 with a first spacing x1. The first material web 3 is in one embodiment a transport path, on which components of the membrane electrode assembly are stacked and connected to each other.

In the embodiment illustrated in FIGS. 1 to 6, the blanks 20 of the membrane 2 are placed directly on the first material web 3, that is to say, the first material web 3 acts as counter-faces for a transfer.

In order to provide the blanks 20 of the membrane 2, a second material web 5 is provided, wherein the blanks 20 are arranged on the second material web with a second spacing x2. The blanks 20 are, for example, formed by means of kiss cutting a laminate comprising the second material web 5 and the membrane 2. The second spacing x2 is smaller than the first spacing x1. The second spacing x2 is in one embodiment practically zero and corresponds only to a width of a cutting edge by means of which the blanks 20 are formed.

The apparatus 1 illustrated in FIGS. 1 to 6 comprises a dispensing edge 6 which extends transversely relative to the direction of the second material web 5 and around which the second material web 5 is guided with a change of direction from a first transport direction I to a second transport direction II in order to release the blanks 20.

The dispensing edge 6 is in the first transport direction I supported so as to be able to be adjusted relative to the second material web 5 and can be adjusted by means of a schematically illustrated adjustment device 60.

For a length compensation during a movement of the dispensing edge 6, the second material web 5 is guided downstream of the dispensing edge 6 via a compensation device 7 comprising a roller 70 which can be acted on pneumatically by means of a pressure cylinder 71.

Upstream of the dispensing edge 6, the second material web 5 is in the embodiment illustrated guided via two driven rollers 50. Downstream of the dispensing edge 6, the second material web 5 is in the embodiment illustrated guided via a roller 51, the roller 70 of the compensation device 7 and a driven roller 52.

The first material web 3 is moved at a conveying speed. For a change of the spacing x1, x2 between the blanks 20 during a transfer to the first material web 3, the second material web 5 is at least in a transfer section illustrated in FIGS. 1 to 6 moved in a discontinuous manner relative to the conveying speed.

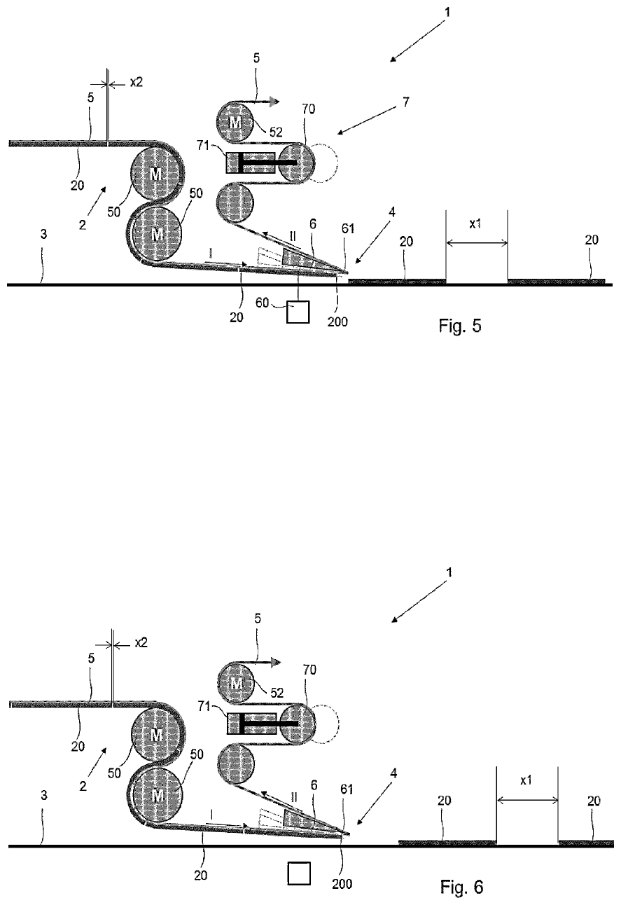

For a tension-free transfer of the blanks 20, the second material web 5 during a transfer to the first material web 3 as illustrated in FIGS. 1 and 2 is moved synchronously relative to the conveying speed of the first material web 3 along the illustrated transfer section. In order to increase the spacing, the second material web 5 is stopped in the embodiment illustrated. The first material web 3 is in this instance moved further at the conveying speed, as schematically illustrated in FIG. 5.

In order to stop the second material web 5, it is braked as illustrated in FIG. 4 until the second material web 5 comes to a stop. In order to bring the second material web 5 from the idle state back up to the transport speed which is synchronous with respect to the conveying speed, the second material web 5 is accelerated, as illustrated in FIG. 6.

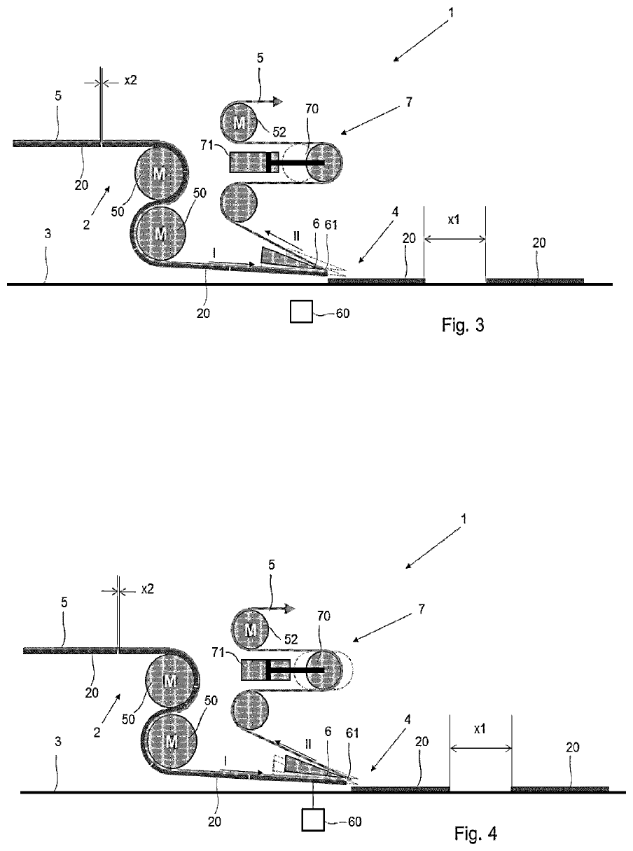

A braking and acceleration of the second material web 5 is carried out without transfer of a blank 20 from the second material web 5 to the first material web 3. To this end, the dispensing edge 6 is raised from the first material web 3, as illustrated in FIGS. 3 to 6.

In order during braking or acceleration to prevent a movement of the second material web 5 over the dispensing edge 6 and consequently a release of a blank 20 from the material web 5 and an exposed portion of the blank 20, the dispensing edge 6 is adjusted relative to the second material web 5 so that a braking and acceleration path is provided for the blanks 20 which are moved discontinuously with the second material web 5.

As illustrated in FIGS. 5 and 6, in order to provide an acceleration path the dispensing edge 6 is adjusted forward in the transport direction I in such a manner that a front end 61 of the dispensing edge 6 is located in the first transport direction I downstream of a front end 200 of a blank 20 which is intended to be transferred after reaching the conveying speed. When the material web 5 is accelerated to the conveying speed, this blank 20 is moved in the direction of the front end 61 of the dispensing edge 6. The offset of the dispensing edge 6 is in this instance selected in such a manner that the material web 5 reaches the transport speed desired for a tension-free transfer when or before the front end 200 of the blank 20 reaches the front end 61 of the dispensing edge 6. For a transfer of the blank 20 at a transport speed which is synchronous with respect to the conveying speed, the dispensing edge 6 is in the embodiment illustrated lowered in the direction of the first material web 3, as illustrated in FIG. 1.

In order to be able to displace the dispensing edge 6 forward in the transport direction again for a subsequent blank 20, during a transfer of the blank 20 the dispensing edge 6 is adjusted backward relative to the second material web 5 in the first transport direction I, as illustrated in FIGS. 2 to 3. In this instance, for a length compensation downstream of the transfer location 4, the roller 70 of the compensation device 7 is adjusted to the right in the drawing plane. After a completed transfer of the blank 20, the dispensing edge 6 is raised from the first material web 3 and the second material web 5 is braked until it comes to a stop. In order during braking to prevent a movement of the following blank 20 over the dispensing edge 6, the dispensing edge 6 is moved forward relative to the second material web 5 in the first transport direction I. In this instance, for a length compensation downstream of the transfer location 4, the roller 70 of the compensation device 7 is adjusted to the left in the drawing plane.

In one embodiment, an adjustment movement of the dispensing edge 6 relative to the second material web 5 when the second material web 5 is braked is sufficient to provide an acceleration path so that, whilst the second material web 5 is stationary, the dispensing edge 6 is also fixed in position. In another embodiment, the dispensing edge 6 is adjusted further forward whilst the second material 5 is stationary.

The driven rollers 50, 52 are operated in a synchronized manner for a reliable transport of the second material web 5. In this instance, the rollers 50 are also used in one embodiment as a removal device for discontinuously unwinding the material web 5 from a store which is not illustrated.

In an alternative embodiment, dancer devices 8 are provided upstream and downstream of the transfer region illustrated in FIGS. 1 to 6.

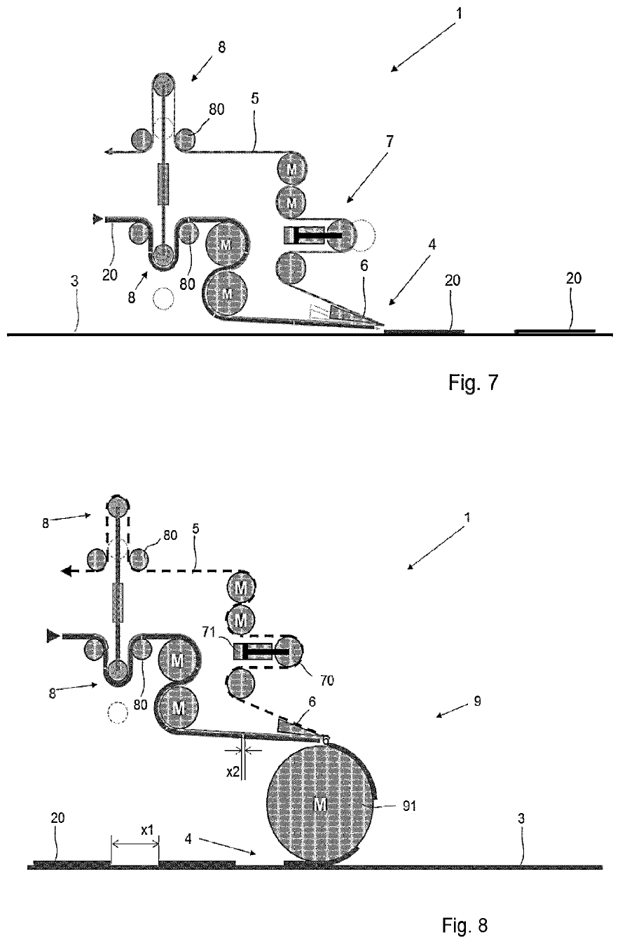

FIG. 7 shows the apparatus 1 according to FIGS. 1 to 6, wherein the second material web is guided upstream and downstream of the transfer section by means of two forcibly guided dancer devices 8 which are coupled to each other. Upstream and downstream of the transfer section, the second material web 5 is transported continuously at a constant transport speed, wherein the transport speed is lower than the transport speed of the first material web 3. In the embodiment illustrated, the coupling of the dancer devices 8 is carried out mechanically. In other embodiments, a technical coupling is provided in control terms.

The coupling of the dancer devices 8 uses the property that a length compensation for a braking where applicable up to a stop and an acceleration of the second material web 5 and a movement synchronously with respect to the conveying speed of the first material web 3 prior to the transfer section is equal in value to a length compensation for a braking where applicable up to a stop and an acceleration and a movement synchronously with respect to the conveying speed of the first material web 3 after the transfer section. During braking and when stationary, the dancer device 8 which is arranged upstream of the transfer section stores a section of the material web 5 in an intermediate manner whilst the dancer device 8 which is arranged downstream of the transfer section releases a stored section of the material web 5. Conversely, the dancer device 8 which is arranged upstream of the transfer section during acceleration and during a movement at the transport speed of the first material web 5 releases an intermediately stored section of the material web 5 whilst the dancer device 8 which is arranged downstream of the transfer section intermediately stores a section of the material web 5.

FIG. 8 shows a second embodiment of an apparatus 1 for transferring a membrane 2 and/or another functional layer to a first material web 3 which is moved at a conveying speed. The apparatus 1 illustrated in FIG. 8 substantially corresponds to the apparatus 1 according to FIG. 7 and for identical components uniform reference numerals are used. In contrast to the apparatus according to FIG. 7, the apparatus 1 illustrated in FIG. 8 additionally comprises a transfer device 9 having a roller 91. The roller 91 is in contact with the first material web 3. It is operated at a rotation speed which is adapted to the conveying speed of the first material web 3 for a tension-free transfer of the blanks 20 from the roller 91 to the first material web 3.

Blanks 20 of the membrane 2 are provided by means of the second material web 5 with a spacing x2 and transferred from the second material web 5 to the roller 91. A surface of the roller 91 consequently acts as a counter-face for the transfer.

In order to increase a spacing of the blanks 20, the second material web 5 is in a transfer section as described above moved in a discontinuous manner relative to the conveying speed.

For the discontinuous movement of the second material web 5, the second material web 5 is guided in a similar manner to FIG. 7 upstream and downstream of the transfer section by means of two forcibly guided dancer devices 8 which are coupled to each other. Upstream and downstream of the transfer section, the second material web 5 is transported at a preferably constant conveying speed, wherein the conveying speed is lower than the conveying speed of the first material web 3. The dancer devices 8 comprise in the embodiment in each case a pressure-loaded roller 80 which contacts the material web 5 in the discontinuously moved section. The illustrations of the dancer devices 8 in FIGS. 7 and 8 are, however, purely schematic and can be implemented in an appropriate manner by the person skilled in the art depending on the application.

The embodiments described above are purely exemplary and numerous modifications are conceivable.

1. An apparatus for transferring a functional layer, in particular a catalyst-coated membrane and/or a gas diffusion layer for a membrane electrode assembly, to a moving first material web, wherein the apparatus is configured to transfer blanks of the functional layer to a counter-face which is moved at a conveying speed with a first spacing, wherein the apparatus has a supply device for supplying the blanks on a second material web and a dispensing edge which extends transversely relative to the direction of the second material web and around which the second material web is guided in order to release the blanks while changing direction from a first transport direction to a second transport direction, wherein the blanks are arranged on the second material web with a second spacing, wherein the first spacing is greater than the second spacing, wherein the supply device is suitable for moving the second material web at least in a transfer section for transfer of a blank in a synchronous manner with respect to the conveying speed and to brake the second material web at least in the transfer section for a change of spacing relative to the conveying speed, and wherein the dispensing edge is supported so as to be able to be adjusted in the first transport direction relative to the second material web and can be adjusted by means of an adjustment device in order to provide a braking and acceleration path for the blanks which are moved in a discontinuous manner with the second material web.

2. The apparatus as claimed in claim 1, wherein the adjustment device is configured, when a blank is transferred, to adjust the dispensing edge relative to the second material web in the first transport direction backward and, when the second material web is braked and/or when the second material web is stationary, to adjust the dispensing edge relative to the second material web in the first transport direction forward.

3. The apparatus as claimed in claim 1, wherein the adjustment device is configured for moving the dispensing edge relative to the counter-face in the direction toward or away from the counter-face in order to bring about a pressing force onto the blank during a transfer and in order to prevent a contact of the blanks or the second material web with the counter-face without transferring a blank.

4. The apparatus as claimed in claim 1, wherein the second material web is guided downstream of the dispensing edge via a compensation device for a length compensation during a movement of the dispensing edge.

5. The apparatus as claimed in claim 1, wherein for the discontinuous movement of the second material web in the transfer section the second material web is guided upstream and/or downstream of the transfer section by means of a forcibly guided dancer device, wherein the second material web is guided in particular upstream and downstream of the transfer section by means of two forcibly guided dancer devices which are coupled to each other.

6. The apparatus as claimed in claim 1, wherein the apparatus is configured to transfer the blanks directly from the second material web to the first material web.

7. A method for transferring a functional layer, in particular a catalyst-coated membrane and/or a gas diffusion layer for a membrane electrode assembly, onto a moving first material web, wherein blanks of the functional layer are transferred to a counter-face which is moved at a conveying speed with a first spacing, wherein the blanks are supplied to the functional layer by means of a second material web with a second spacing, wherein the first spacing is larger than the second spacing, wherein the second material web in order to release the blanks is guided around a dispensing edge which extends transversely relative to the direction of the second material web while changing direction from a first transport direction to a second transport direction, wherein the second material web at least in a transfer section for a transfer of a blank moves synchronously with respect to the conveying speed and to change spacing is braked relative to the conveying speed, and wherein the dispensing edge is adjusted in the first transport direction relative to the second material web in order to provide a braking and acceleration path for the blanks which are moved discontinuously with the second material web.

8. The method as claimed in claim 7, wherein, during a transfer of a blank, the dispensing edge is adjusted backward relative to the second material web in the first transport direction and, when the second material web is braked and/or when the second material web is stationary, the dispensing edge is adjusted forward relative to the second material web in the first transport direction.

9. The method as claimed in claim 7, wherein the dispensing edge is moved relative to the counter-face at the beginning of the transfer in the direction toward the counter-face and after the transfer is moved away therefrom in order to brim about a pressing force on the blank during the transfer and in order to prevent a contact of the blanks or the second material web with the counter-face without transferring a blank.

10. The method as claimed in claim 7, wherein the second material web is guided downstream of the dispensing edge via a compensation device for a length compensation during a movement of the dispensing edge.

11. The method as claimed in claim 7, wherein for the discontinuous movement of the second material web in the transfer section the second material web is guided upstream and/or downstream of the transfer section by means of a forcibly guided dancer device, wherein in particular the second material path is guided upstream and downstream of the transfer section by means of two forcibly guided dancer devices which are coupled to each other.

12. The method as claimed in claim 7, wherein the blanks are transferred directly from the second material web to the first material web.
